(19) United States
(12) Patent Application Publication
(10) Pub. No.: US 2025/0062139 A1
(43) Pub. Date: Feb. 20, 2025

(54) FURNACE INNER TUBE FOR PROCESS UNIFORMITY

(71) Applicant: TAIWAN SEMICONDUCTOR MANUFACTURING COMPANY, LTD., Hsinchu (TW)

(72) Inventors: De-Wei YU, Pingtung (TW); Chien-Chia CHENG, Hsinchu (TW); Ming-Hua YU, Hsinchu (TW); Hsueh-Chang SUNG, Hsinchu (TW); Chii-Horng LI, Hsinchu (TW)

(21) Appl. No.: 18/234,988

(22) Filed: Aug. 17, 2023

(51) Int. Cl. H01L 21/67; F27B 17/00; H01L 29/66

(52) U.S. Cl. CPC H01L 21/67017; F27B 17/0025; H01L 21/67109; H01L 29/66545

(57) ABSTRACT

Embodiments of the present disclosure provide a furnace for semiconductor processing that includes an inner tube defining a reaction chamber and including a sidewall defined along a longitudinal axis of the inner tube and including one or more slits defined through the sidewall in a radial direction with respect to the longitudinal axis. The one or more slits include at least one of a first slit with a width in a range between 10 mm and 100 mm, or a plurality of separate slits with a total number in a range between 2 and 15. The inner tube includes a closed end substantially enclosing the reaction chamber and an open end opposite the closed end with respect to the longitudinal axis. The reaction chamber is configured to be loaded with one or more semiconductor wafers via the open end.

### BACKGROUND

Semiconductor devices are used in a variety of electronic applications, such as personal computers, cell phones, digital cameras, and other electronic equipment. Semiconductor devices are fabricated by sequentially depositing insulating or dielectric layers, conductive layers, and semiconductive layers of material over a semiconductor substrate, and patterning or processing the substrate and/or the various material layers using lithography to form circuit components and elements thereon and to form integrated circuits. The uniformity of the layers deposited on the semiconductor substrate is affected and controlled by regulating process parameters such as temperature of the wafer, reaction chamber pressure, flow path and rate of reactant gases, process time or duration, and other factors. Typical hardware designs are not able to achieve uniform layer thickness. Embodiments of the present disclosure provide solutions, for semiconductor processing, that solve one or more problems set forth above and/or other problems in the art.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic side view, in partial cross-section, that illustrates an example furnace for semiconductor processing according to embodiments of the present disclosure.

FIG. 2 is a schematic top view, in partial cross-section, that illustrates a portion of another example furnace according to embodiments of the present disclosure.

FIG. 3 is a perspective view of the example furnace of FIG. 2 according to embodiments of the present disclosure.

FIG. 4 is a schematic perspective view that illustrates an example inner tube according to embodiments of the present disclosure.

FIGS. 5-9 are schematic perspective views that illustrate various example inner tubes according to embodiments of the present disclosure.

FIGS. 10-36 are diagrammatic views that illustrate various example sidewall slits according to embodiments of the present disclosure.

FIG. 37 is a flow chart that illustrates a method of semiconductor processing according to embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and also may include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. In the present disclosure, a source/drain region(s) may refer to a source or a drain, individually or collectively dependent upon the context.

Embodiments of the present disclosure provide furnace inner tube hardware designs that are configured for enhanced pumping efficiency and tuning of pumping efficiency top to bottom, which can result in improved uniform layer thickness both within wafer and within batch. For example, testing has shown that the gain in layer thickness uniformity may exceed 30% improvement compared to typical hardware designs.

Implementation of a polycrystalline silicon (poly Si) gapfill process using embodiments of the present disclosure helps illustrate various advantages of this approach. For example, seam/void (with potential for spacer to fill in) formed during poly Si gapfill may increase spacer material and/or poly Si remaining after removal of the dummy gate, which introduces potential risk for abnormal wafer acceptance test (WAT) after high K and metal gate deposition. The current approach for poly Si gapfill is cyclic Si deposition (Si-containing precursors such as SiH₄)/Cl₂ etched Si (halogen gas)/Si deposition/etc. until the aspect ratio (e.g., remaining trench depth to trench width) is less than 0.5. The cyclic process needs uniform within wafer thickness control. Otherwise, the non-uniformity can negatively affect Si thickness control (Si film roughness and/or V-shape) for poly Si gapfill, with worsening seam/void performance. For example, greater Si deposition at wafer center or greater Cl₂ etched Si (reduction in Si thickness) at wafer edge may result in relatively thinner Si thickness at wafer edge, and poor Si film roughness and/or V-shape for poly Si gapfill. Therefore, within wafer Si deposition or Cl₂ etched Si uniformity (center-edge thickness loading) is very important. Inner tube hardware designs of the present disclosure can improve within wafer uniformity (center-edge thickness difference) of Si deposition and/or Cl₂ etched Si amount, as described in more detail below.

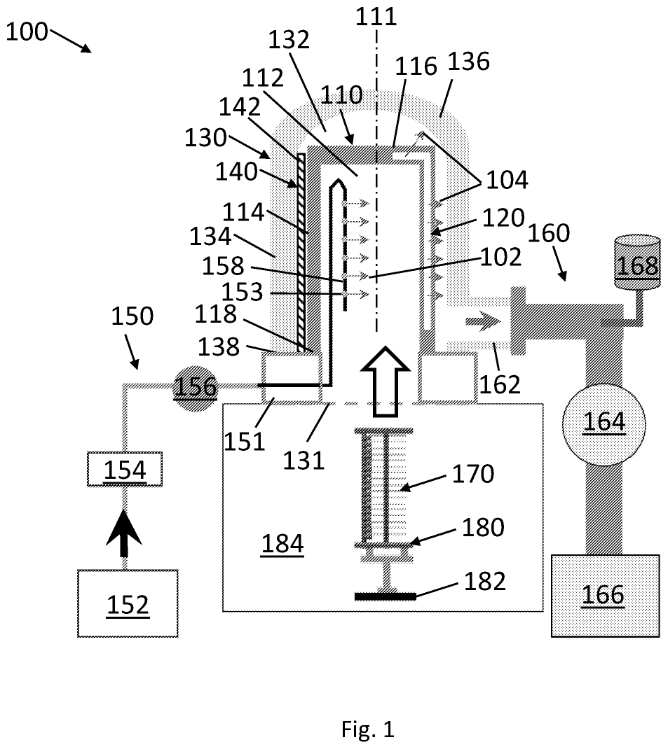

FIG. 1 is a schematic side view, in partial cross-section, that illustrates an example furnace 100 for semiconductor processing according to embodiments of the present disclosure. The furnace 100 generally includes an inner tube 110 including one or more slits 120, an outer tube 130, one or more heat sources 140, an injector assembly 150, and an exhaust assembly 160.

The inner tube 110 may be formed from a material that is heat shielding, heat resistant, and/or insulating (e.g., quartz). A reaction chamber 112 is defined inside the inner tube 110. The reaction chamber 112 may refer to a portion of the furnace 100 where processing takes place. The inner tube 110 includes a sidewall 114 (e.g., a cylindrical sidewall) defined along a longitudinal axis 111 of the inner tube 110. The one or more slits 120, described in more detail below, are defined through the sidewall 114 in a radial direction with respect to the longitudinal axis 111. The inner tube 110 includes a closed end 116 substantially enclosing the reaction chamber 112. For example, the inner tube 110 may be closed at the top when the furnace 100 is oriented vertically. The inner tube 110 includes an open end 118 opposite the closed end 116 with respect to the longitudinal axis 111. For example, the furnace 100 may be open at the bottom when the furnace 100 is oriented vertically. In some embodiments, the open end 118 may include a flange that is configured to extend below and/or around a corresponding shoulder of the outer tube 130. An insulating material may be associated with an interface of the inner tube 110 and the outer tube 130 (e.g., between the flange and the shoulder) and configured to block a gap between the inner tube 110 and the outer tube 130 to reduce heat loss (e.g., from the inner tube 110).

The reaction chamber 112 is configured to be loaded with one or more semiconductor wafers 170 via the open end 118. For example, to be loaded into the reaction chamber 112, the one or more semiconductor wafers 170 may be disposed in a wafer boat 180 that is configured to be loaded into the reaction chamber 112. For example, the wafer boat 180 may be loaded into the reaction chamber 112 by inserting the wafer boat 180 through the open end 118 by opening a door 131 and, for example, raising the wafer boat 180 in a vertical direction, when the furnace 100 is oriented vertically. In some embodiments, the wafer boat 180 may contain up to 156 semiconductor wafers 170 for batch processing. As shown in FIG. 1, the wafer boat 180 may pass through a loading area 184 located outside the furnace 100. For example, the loading area 184 may define a controlled environment (e.g., O₂ less than 5 ppm).

The outer tube 130 surrounds the inner tube 110. An enclosure 132 is defined inside the outer tube 130. The outer tube 130 includes a sidewall 134 (e.g., a cylindrical sidewall) defined along the longitudinal axis 111. For example, the sidewall 134 of the outer tube 130 may be concentric with the sidewall 114 of the inner tube 110. The outer tube 130 includes a closed end 136 substantially enclosing the enclosure 132 and the inner tube 110. For example, the outer tube 130 may be closed at the top when the furnace 100 is oriented vertically. The outer tube 130 includes an open end 138 opposite the closed end 136 with respect to the longitudinal axis 111. For example, the furnace 100 may be open at the bottom when the furnace 100 is oriented vertically.

The door 131 is coupled to a body 151 of the injector assembly 150 and is configured to move (e.g., hinged or sliding) between an open position, for accessing the inner tube 110 from the open end 118, and a closed position, for isolating the reaction chamber 112 from the outside environment. The position of the door 131, to capture the transition between the open and closed positions, is represented by a dashed line. The wafer boat 180 may include a lid plate 182 that is configured to be coupled to (e.g., sealed with) the open end 118 of the inner tube 110 and/or the body 151 of the injector assembly 150 (described below), to isolate the reaction chamber 112 from the environment outside the inner tube 110 (e.g., the enclosure 132).

The outer tube 130 is configured to accommodate the inner tube 110 and the one or more heat sources 140. The one or more heat sources 140 are configured to cause a temperature change (e.g., heating) in the reaction chamber 112. Heating the reaction chamber 112 may be configured to promote (e.g., accelerate and/or cause) a process (e.g., a reaction) in the reaction chamber 112.

The one or more heat sources 140 may include one or more heating elements 142 (e.g., electric heating elements and/or gas heating elements). For example, a first heating element, of the one or more heating elements 142, may be disposed next to (e.g., contacting, spaced from, and/or surrounding) the sidewall 114. In some embodiments, a second heating element may be disposed next to (e.g., contacting, spaced from, and/or surrounding) the closed end 116.

The injector assembly 150 may be coupled to the inner tube 110 (e.g., coupled to the sidewall 114 of the inner tube 110 near the closed end 118) and/or the outer tube 130 (e.g., coupled to the sidewall 134 of the outer tube 130 near the closed end 138). For example, the body 151 of the injector assembly 150 may be coupled to both the inner tube 110 and the outer tube 130 as shown in FIG. 1. For example, a flow line associated with the injector assembly 150 may pass through the body 151. The injector assembly 150 may be configured to inject one or more process gases 102 into the reaction chamber 112 (e.g., via a gas inlet of the reaction chamber 112) through one or more injectors 158.

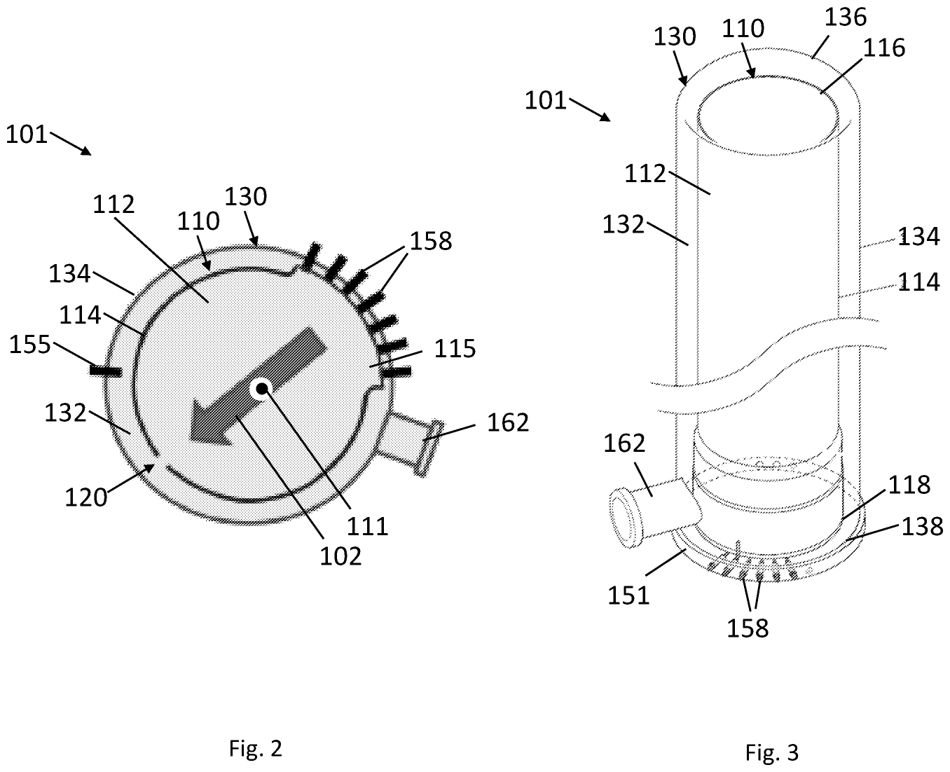

The injector assembly 150 may include a gas source 152, a flow device 154 (e.g., a mass flow controller) configured to measure and control the flow of gas, a valve 156 configured to open or close the injector assembly 150 to the flow of gas, the one or more injectors 158, and flow lines associated with the injector assembly 150. The injector assembly 150 is in fluid communication with the reaction chamber 112. For example, the one or more process gases 102 may flow from the gas source 152 to the one or more injectors 158, via the flow device 154, the valve 156, and the associated flow lines. The arrangement of the one or more injectors 158 is described in more detail below in connection with FIGS. 2-3.

The exhaust assembly 160 is coupled to the outer tube 130 (e.g., coupled to the sidewall 134 of the outer tube 130). For example, a flow line associated with the exhaust assembly 160 may be coupled to an exhaust port 162 defined on the sidewall 134 of the outer tube 130 at a location between the open end 118 of the inner tube 110 and the closed end 136 of the outer tube 130. The exhaust assembly 160 may be configured to exhaust one or more exhaust gases 104 from the reaction chamber 112 via the one or more slits 120 of the inner tube 110.

The exhaust assembly 160 may include the exhaust port 162, a valve 164 configured to regulate the flow of gas through the exhaust assembly 160, a pump 166 configured to create a vacuum pressure (e.g., in a range between about 10 mTorr and about 50 Torr) in the reaction chamber 112, a pressure gauge 168 configured to measure a pressure in the exhaust assembly 160, and flow lines associated with the exhaust assembly 160. The exhaust assembly 160 is in fluid communication with the reaction chamber 112. For example, the one or more exhaust gases 104 may flow from the reaction chamber 112 to the pump 166, via the one or more slits 120, the enclosure 132, the exhaust port 162, the valve 164, and the associated flow lines.

FIG. 2 is a schematic top view, in partial cross-section, that illustrates a portion of another example furnace 101 according to embodiments of the present disclosure. FIG. 3 is a perspective view of the example furnace 101 of FIG. 2 according to embodiments of the present disclosure. In FIG. 3, at least the sidewall 134 and the closed end 136, of the outer tube 130, are invisible to make the inner tube 110 visible in the perspective view. Note that furnace 101 differs slightly from furnace 100. However, any description provided below with respect to FIGS. 2-3 (e.g., related to the one or more injectors 158) may be equally applicable to both furnaces, without limitation. For example, in contrast to furnace 100, a portion 115 of furnace 101 extends radially outwardly with respect to the generally cylindrical portion of the sidewall 114. In some embodiments, the portion 115 may be a portion of the inner tube 110 or an aspect of a piece that is associated with the inner tube 110, as described in more detail below. Also, the exhaust port 162, of furnace 101, is located at a different circumferential position compared to the one or more slits 120.

As shown in FIGS. 2-3, the one or more injectors 158 include a plurality of injectors 158 (e.g., with a total number in a range between 2 and 10, such as 7 injectors as shown) that are arranged at different circumferential positions about the sidewall 114 (e.g., about longitudinal axis 111). The plurality of injectors 158 may extend around the sidewall 114 by a certain angle (e.g., in a range between about 60 degrees and about 90 degrees). Each injector, of the plurality of injectors 158, may include multiple injection ports 153 (shown in FIG. 1) located at different heights with respect to the longitudinal axis 111 to promote uniform injection, uniform flow, and/or uniform concentration of the one or more process gases 102 within the reaction chamber 112. The flow of gas from the one or more injectors 158, across the reaction chamber 112, to the one or more slits 120 (as shown in FIGS. 1 and 2), is characteristic of a cross-flow reactor (CFR). In some embodiments, an alternative system such as a normal-flow reactor (NFR) in which the flow of gas is introduced from the bottom of the inner tube 110, may be used. The present disclosure may be equally applicable to both reactor types, without limitation.

As shown in FIG. 2, one or more other injectors (e.g., injector 155) may be associated with the inner tube 110 and/or the outer tube 130 for injecting other gases (e.g., inert gas, such as nitrogen, for purging or halogen gas for cleaning) into the reaction chamber 112 and/or the enclosure 132.

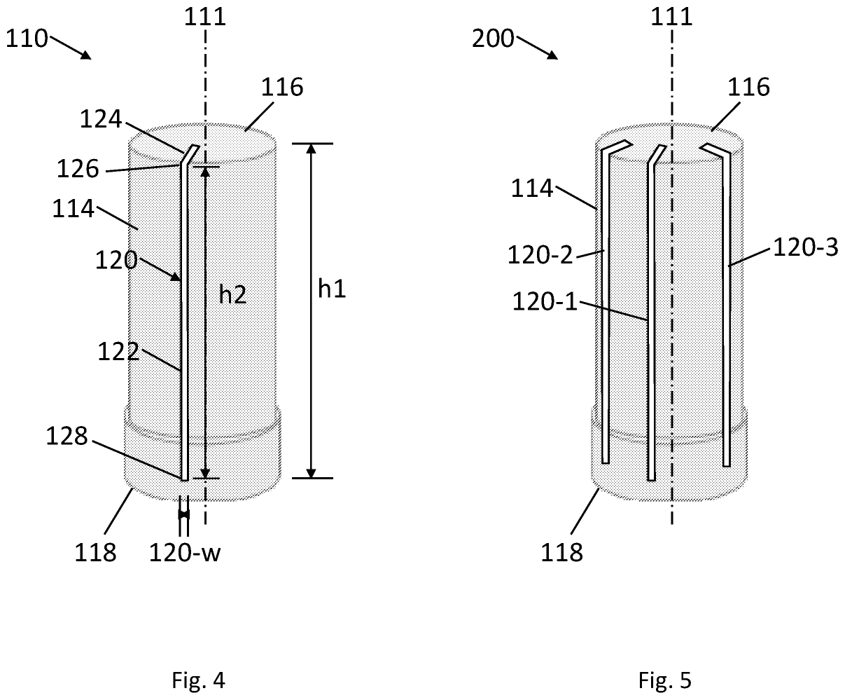

FIG. 4 is a schematic perspective view that illustrates an example inner tube 110 according to embodiments of the present disclosure. A total height h1 of the inner tube 110 between the closed end 116 and the open end 118 may be in a range between about 1000 mm and about 2000 mm. For example, the total height h1 of the inner tube 110 may be slightly less than a total height of the outer tube 130 (e.g., in a range between about 1150 mm and about 2150 mm). The inner tube 110 may include a slit 120 (e.g., with a total number of slits in a range between 1 and 15, such as consisting of only 1 slit as shown). As described above, the slit 120 is defined through the sidewall 114 in a radial direction with respect to the longitudinal axis 111. A thickness of the inner tube 110 in the radial direction with respect to the longitudinal axis 111 may be in a range between about 10 mm and about 50 mm. Accordingly, a radial dimension of the slit 120 may be in a range between about 10 mm and about 50 mm (e.g., corresponding to the thickness of the inner tube 110).

In some embodiments, the slit 120 may include a sidewall portion 122 defined in the sidewall 114 and a top portion 124 defined in the closed end 116 (e.g., defined in the top of the inner tube 110). According to the present disclosure, the closed end 116 substantially encloses the reaction chamber 112 even though some flow of gas will occur through the top portion 124 of the slit 120. The sidewall portion 122 and top portion 124 may be connected to each other. In some other embodiments, the slit 120 may include only the sidewall portion 122 and not the top portion 124. However, embodiments that include the top portion 124 of the slit 120 can, independent of or in addition to the benefits associated with increasing slit width and/or slit number (as described in more detail below), provide enhanced pumping efficiency and tuning of pumping efficiency top to bottom, which can result in improved uniform layer thickness both within wafer and within batch.

As shown in FIG. 4, the sidewall portion 122 is parallel to the longitudinal axis 111 and defines a first end 126 (e.g. at the closed end 116) and a second end 128 opposite the first end 126 with respect to the longitudinal axis 111. A full height h2 between the first end 126 and the second end 128 of the slit 120 (e.g., full height of the sidewall portion 122) may be in a range between about 1000 mm and about 2000 mm. A diameter of the inner tube 110 may be in a range between about 330 mm and about 360 mm. A radial dimension of the top portion 124 may be in a range between about 0 mm and about 180 mm (e.g., extending across the closed end 116 of the inner tube 110 by up to about ½ the diameter of the inner tube 110).

A width 120-w of the slit 120 (e.g., width of the sidewall portion 122 and/or the top portion 124) may be in a range between 10 mm and 100 mm. As described in more detail below, the width 120-w may be fixed or variable along the longitudinal axis 111. The sidewall portion 122 and the top portion 124 may be equal in width or have different widths. For example, the top portion 124 may be wider or narrower than the sidewall portion 122.

FIGS. 5-9 are schematic perspective views that illustrate various example inner tubes according to embodiments of the present disclosure. Note that the arrangement and/or geometry of the one or more slits 120 differ slightly between the various examples. However, any description provided above with respect to FIGS. 1-4 (e.g., related to the furnace, inner tube, etc.) may be equally applicable to the various examples, without limitation.

As shown in FIG. 5, inner tube 200 may include a plurality of separate slits 120-1, 120-2, 120-3 (collectively, “120”) (e.g., with a total number of slits in a range between 2 and 15, such as including 3 slits as shown) that are arranged at different circumferential positions about the sidewall 114 (e.g., about longitudinal axis 111). The separate slits 120 may be spaced uniformly or non-uniformly around the sidewall 114. For example, each of the separate slits 120 may be separated by a certain angle (e.g., in a range between about 10 degrees and about 90 degrees). In some embodiments, in order to ensure cross-flow of the one or more process gases (as described above) and/or from structural point of view, the plurality of separate slits 120 may be positioned only within a limited circumferential portion of the sidewall 114 (e.g., in a range between about 10 degrees and about 180 degrees). The full height and/or width of the separate slits 120 may be the same or different.

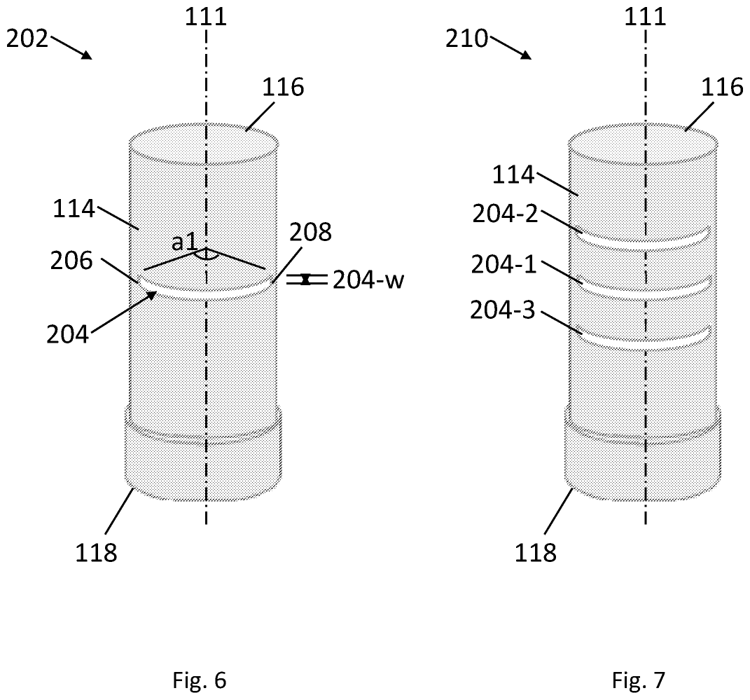

As shown in FIG. 6, inner tube 202 may include a slit 204 that is defined in the sidewall 114 between the closed end 116 and the open end 118. The slit 204 is perpendicular to the longitudinal axis 111. The slit 204 defines a first end 206 and a second end 208 opposite the first end 206 with respect to the circumferential direction. In some embodiments, in order to ensure cross-flow of the one or more process gases (as described above) and/or from structural point of view, the slit 204 may extend only around a limited circumferential portion of the sidewall 114 (e.g., a certain angle around the inner tube 202). For example, an angle a1 between the first end 206 and the second end 208 of the slit 204 may be in a range between about 10 degrees and about 180 degrees (e.g., extending around the circumference of the sidewall 114 by a distance of up to about ½ the circumference of the inner tube 110). A width 204-w of the slit 204 may be in a range between 10 mm and 100 mm. As described in more detail below, the width 204-w may be fixed or variable along the circumference.

As shown in FIG. 7, inner tube 210 may include a plurality of separate slits 204-1, 204-2, 204-3 (collectively, “204”) (e.g., with a total number of slits in a range between 2 and 15, such as including 3 slits as shown) that are arranged at different longitudinal positions (heights) along the sidewall 114 (e.g., along longitudinal axis 111). The separate slits 204 may be spaced uniformly or non-uniformly along the longitudinal axis 111. For example, each of the separate slits 204 may be separated by a certain distance (e.g., in a range between about 50 mm and about 1000 mm). The angle and/or width of the separate slits 204 may be the same or different.

Inner tube hardware designs of the present disclosure (e.g., those illustrated in FIGS. 4-7) having parallel slits (e.g., all slits in the same direction without any slits in a different direction), compared to designs with slits in multiple directions, can provide benefits to manufacturability and/or from structural point of view.

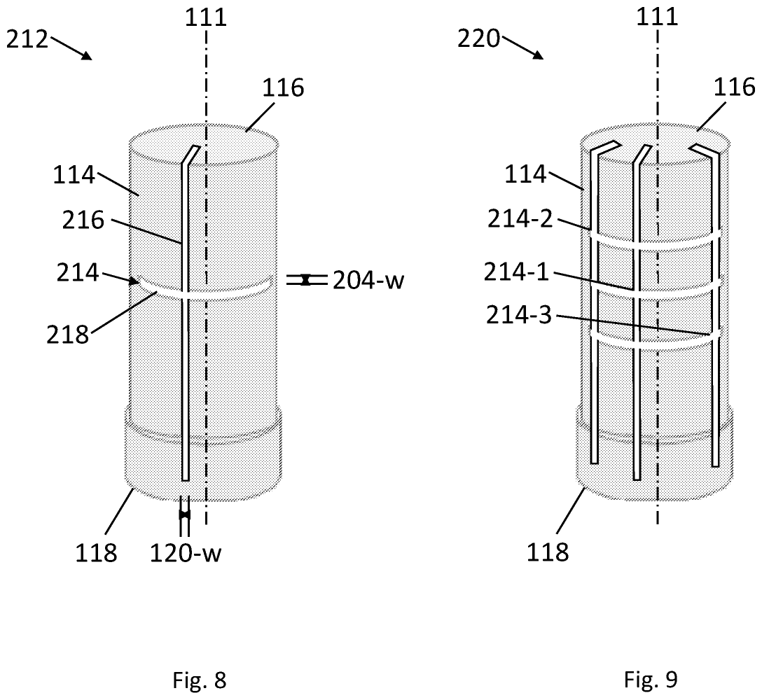

As shown in FIG. 8, inner tube 212 may include a cross-slit 214 that includes a first portion (or “first segment”) 216 parallel to the longitudinal axis 111 and a second portion (or “second segment”) 218 perpendicular to the first portion 216. For example, the cross-slit 214 is a combination of the slit 120 (shown in FIG. 4) and the slit 204 (shown in FIG. 6). The cross-slit 214 may be symmetrical or non-symmetrical with respect to either the longitudinal axis 111 or the circumferential direction.

As shown in FIG. 9, inner tube 220 may include a plurality of separate cross-slits 214-1, 214-2, 214-3 (collectively, “214”) (e.g., with a total number of cross-slits in a range between 2 and 15, such as including 3 cross-slits as shown). For example, cross-slit 214-1 may include the first and second segments in the center, cross-slit 214-2 may include the first segment on the left and the second segment at the top, and cross-slit 214-3 may include the first segment on the right and the second segment at the bottom. As shown in FIG. 9, the 3 cross-slits define a grid with 9 points of intersection. The different segments may be spaced uniformly or non-uniformly with respect to either the longitudinal axis 111 or the circumferential direction.

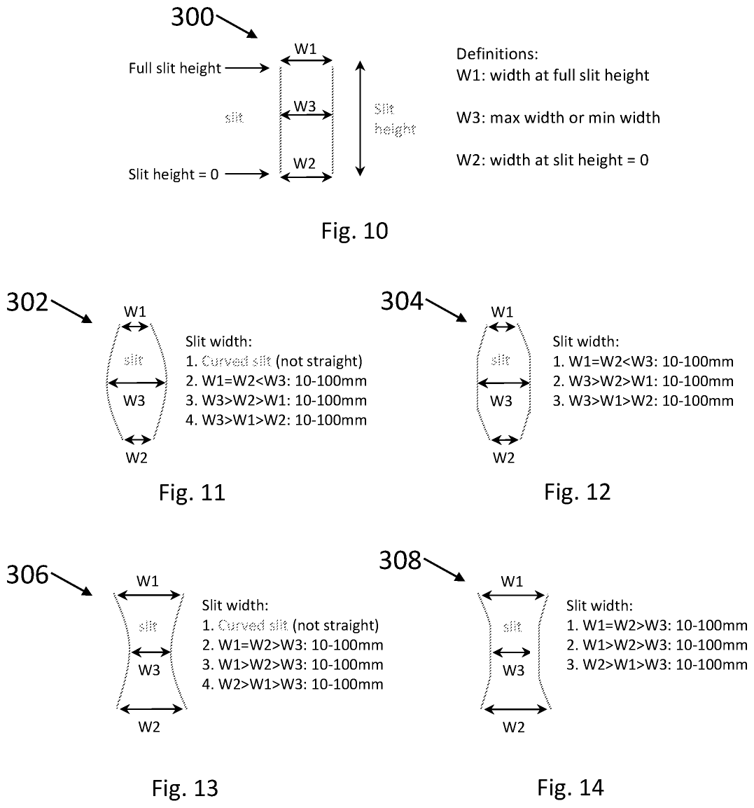

Inner tube hardware designs of the present disclosure (e.g., those illustrated in FIGS. 4-9) having one or more slits with a width of 10 mm or greater (e.g., in a range between 10 mm and 100 mm), compared to slit widths less than 10 mm (e.g., 5 mm), and/or including a plurality of separate slits with a total number in a range between 2 and 15, compared to having only a single slit, can provide enhanced pumping efficiency and tuning of pumping efficiency top to bottom, which can result in improved uniform layer thickness both within wafer and within batch. The benefits described above may be further enhanced and/or refined by optimizing the shape and width of individual slits, as described below in connection with FIGS. 10-36.

FIGS. 10-36 are diagrammatic views that illustrate various example sidewall slits according to embodiments of the present disclosure.

As shown in FIG. 10, reference slit 300 (e.g., being parallel to the longitudinal axis 111) defines a first end at full slit height (e.g., corresponding to first end 126 of slit 120), a second end at slit height equal to zero (e.g., corresponding to second end 128 of slit 120), a full height between the first end and the second end (e.g., corresponding to the full height h2 between the first end 126 and the second end 128), a first width W1 at the first end that corresponds to the full height, a second width W2 at the second end that corresponds to slit height equal to zero, and a third width W3 between the first end and the second end that corresponds to the maximum width or the minimum width of the reference slit 211.

As shown in FIG. 11, edges of slit 302 are curved (e.g., concave), and the third width W3 is a maximum width of the slit 302 (W3>W1 and W3>W2). For example, the relative widths may be W1=W2<W3, W3>W2>W1, or W3>W1>W2.

As shown in FIG. 12, slit 304 is the same as slit 302 except edges of the slit 304 are straight. For example, the slit 304 may have a middle portion with parallel edges, a top portion with edges that narrow towards the top, and a bottom portion with edges that narrow towards the bottom. In general, slit 304 may have the same general profile (e.g., concave) as slit 302, based on the straight portions being angled with respect to each other, as shown.

As shown in FIG. 13, edges of the slit 306 are curved (e.g., convex), and the third width W3 is a minimum width of slit 217 (W3<W1 and W3<W2). For example, the relative widths may be W1=W2>W3, W1>W2>W3, or W2>W1>W3.

As shown in FIG. 14, slit 308 is the same as slit 306 except edges of the slit 308 are straight. For example, the slit 308 may have a middle portion with parallel edges, a top portion with edges that widen towards the top, and a bottom portion with edges that widen towards the bottom. In general, slit 308 may have the same general profile (e.g., concave) as slit 306, based on the straight portions being angled with respect to each other, as shown.

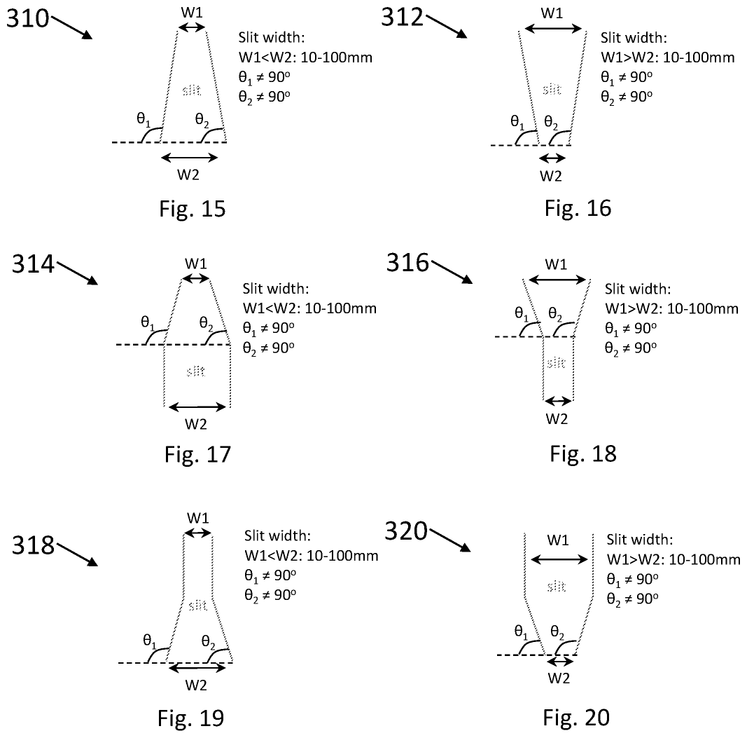

As shown in FIGS. 15-20, a first edge of the slit is at a first angle θ₁ that is non-parallel with respect to the longitudinal axis 111 and a second edge of the slit is at a second angle 62 that is non-parallel with respect to the longitudinal axis 111.

In FIG. 15, the width of slit 310 varies linearly from the first end to the second end and the first width W1 is less than the second width W2 (e.g., narrowing towards the top).

In FIG. 16, the width of slit 312 varies linearly from the first end to the second end and the first width W1 is greater than the second width W2.

In FIG. 17, the width of slit 314 varies linearly along a first portion of the slit 314 that includes the first end, the width of the slit 314 is fixed along a second portion of the slit 314 that includes the second end, and the first width W1 is less than the second width W2.

In FIG. 18, the width of slit 316 varies linearly along the first portion of the slit 316 that includes the first end, the width of the slit 316 is fixed along the second portion of the slit 316 that includes the second end, and the first width W1 is greater than the second width W2.

In FIG. 19, the width of slit 318 is fixed along the first portion of the slit 318 that includes the first end, the width of the slit 318 varies linearly along the second portion of the slit 318 that includes the second end, and the first width W1 is less than the second width W2.

In FIG. 20, the width of slit 320 is fixed along the first portion of the slit 320 that includes the first end, the width of the slit 320 varies linearly along the second portion of the slit 320 that includes the second end, and the first width W1 is greater than the second width W2.

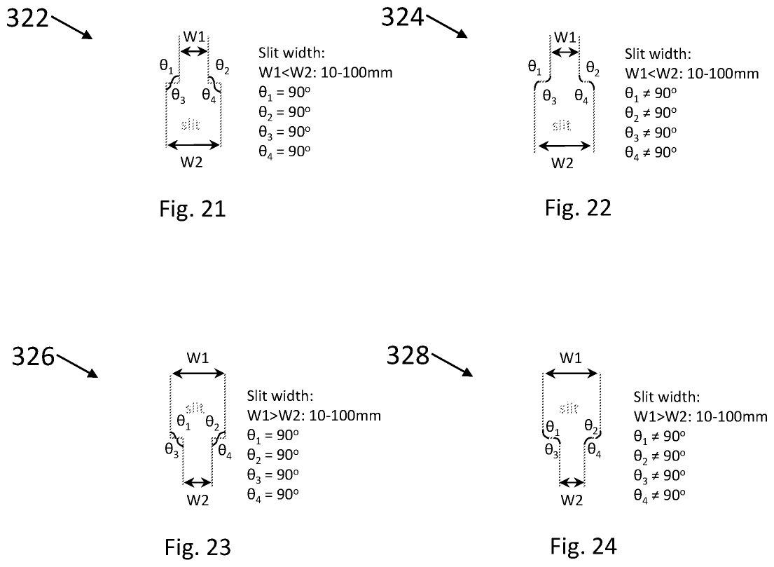

As shown in FIGS. 21-24, the width of the slit is fixed at first width W1 along a first portion of the slit that includes the first end, the width of the slit is fixed at second width W2 along a second portion of the slit that includes the second end, first and second shoulders are defined, at an intersection of the first and second portions, along edges of the slit, one or more step changes in the width are defined at the first and second shoulders, and the first and second shoulders define one or more angles with respect to the edges.

In FIG. 21, with reference to slit 322, the first width W1 is less than the second width W2 and the one or more angles (θ₁, θ₂, θ₃, θ₄) are right angles.

In FIG. 22, with reference to slit 324, the first width W1 is less than the second width W2 and the one or more angles (θ₁, θ₂, θ₃, θ₄) are oblique angles (angles that are not equal to 90° and which also may be referred to herein as “non-right angles”).

In FIG. 23, with reference to slit 326, the first width W1 is greater than the second width W2 and the one or more angles (θ₁, θ₂, θ₃, θ₄) are right angles.

In FIG. 24, with reference to slit 328, the first width W1 is greater than the second width W2 and the one or more angles (θ₁, θ₂, θ₃, θ₄) are oblique angles.

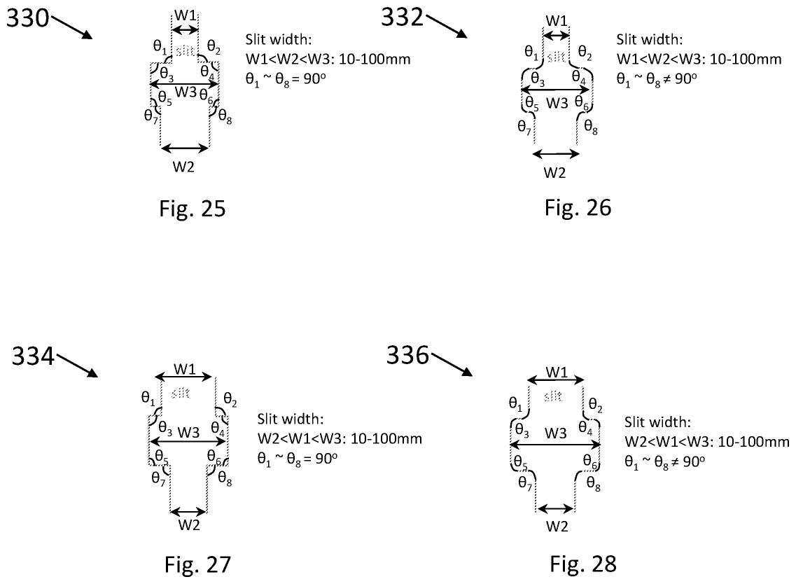

As shown in FIGS. 25-36, the width of the slit is fixed at the first width W1 along a first portion of the slit that includes the first end, the width of the slit is fixed at the second width W2 along a second portion of the slit that includes the second end, the width of the slit is fixed at the third width W3 along a third portion of the slit between the first end and the second end, a plurality of shoulders are defined, between the first and third portions and between the second and third portions, along edges of the slit, one or more step changes in the width are defined at the plurality of shoulders, and the plurality of shoulders define one or more angles with respect to the edges.

In FIG. 25, with reference to slit 330, the first width W1 is less than the second width W2, the second width W2 is less than the third width W3, and the one or more angles (θ₁-θ₈) are right angles.

In FIG. 26, with reference to slit 332, the first width W1 is less than the second width W2, the second width W2 is less than the third width W3, and the one or more angles (θ₁-θ₈) are oblique angles.

In FIG. 27, with reference to slit 334, the first width W1 is greater than the second width W2, the first width W1 is less than the third width W3, and the one or more angles (θ₁-θ₈) are right angles.

In FIG. 28, with reference to slit 336, the first width W1 is greater than the second width W2, the first width W1 is less than the third width W3, and the one or more angles (θ₁-θ₈) are oblique angles.

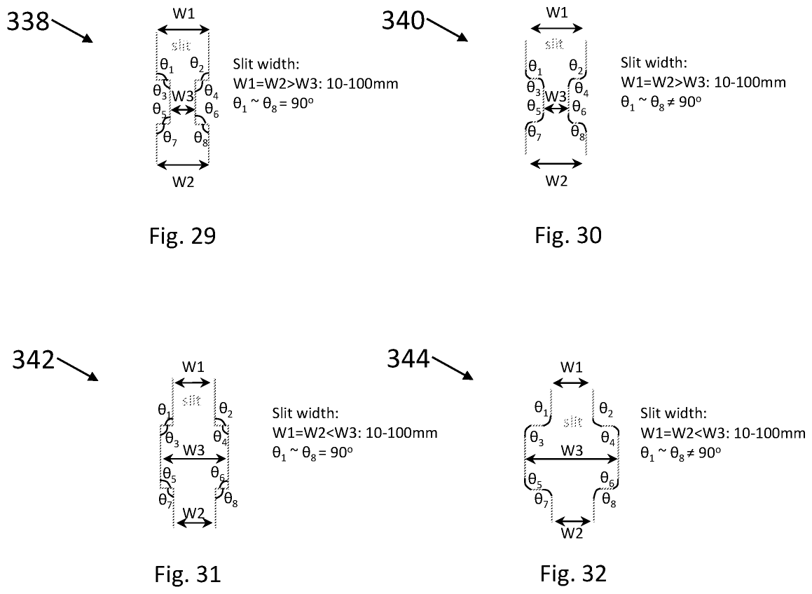

In FIG. 29, with reference to slit 338, the first width W1 is equal to the second width W2, the first width W1 is greater than the third width W3, and the one or more angles (θ₁-θ₈) are right angles.

In FIG. 30, with reference to slit 340, the first width W1 is equal to the second width W2, the first width W1 is greater than the third width W3, and the one or more angles (θ₁-θ₈) are oblique angles.

In FIG. 31, with reference to slit 342, the first width W1 is equal to the second width W2, the first width W1 is less than the third width W3, and the one or more angles (θ₁-θ₈) are right angles.

In FIG. 32, with reference to slit 344, the first width W1 is equal to the second width W2, the first width W1 is less than the third width W3, and the one or more angles (θ₁-θ₈) are oblique angles.

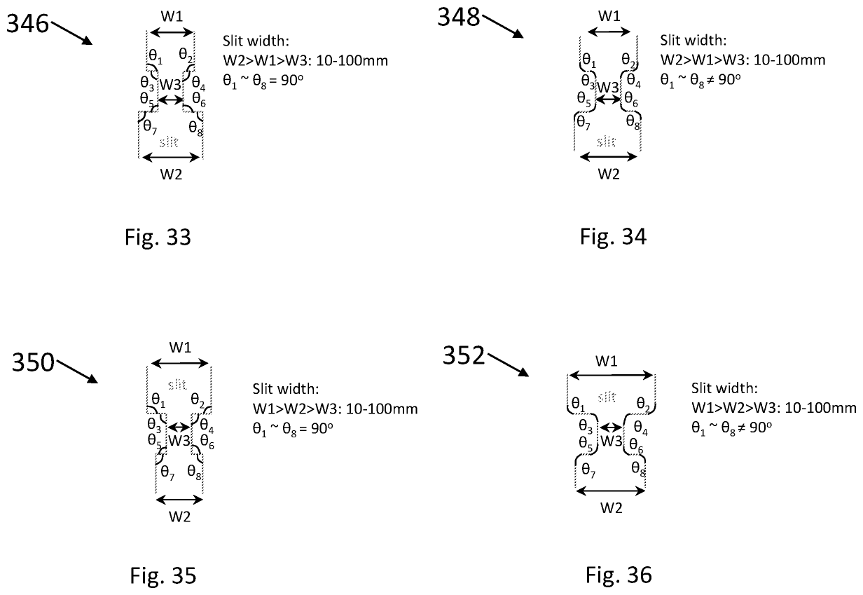

In FIG. 33, with reference to slit 346, the first width W1 is less than the second width W2, the first width W1 is greater than the third width W3, and the one or more angles (θ₁-θ₈) are right angles.

In FIG. 34, with reference to slit 348, the first width W1 is less than the second width W2, the first width W1 is greater than the third width W3, and the one or more angles (θ₁-θ₈) are oblique angles.

In FIG. 35, with reference to slit 350, the first width W1 is greater than the second width W2, the second width W2 is greater than the third width W3, and the one or more angles (θ₁-θ₈) are right angles.

In FIG. 36, with reference to slit 352, the first width W1 is greater than the second width W2, the second width W2 is greater than the third width W3, and the one or more angles (θ₁-θ₈) are oblique angles.

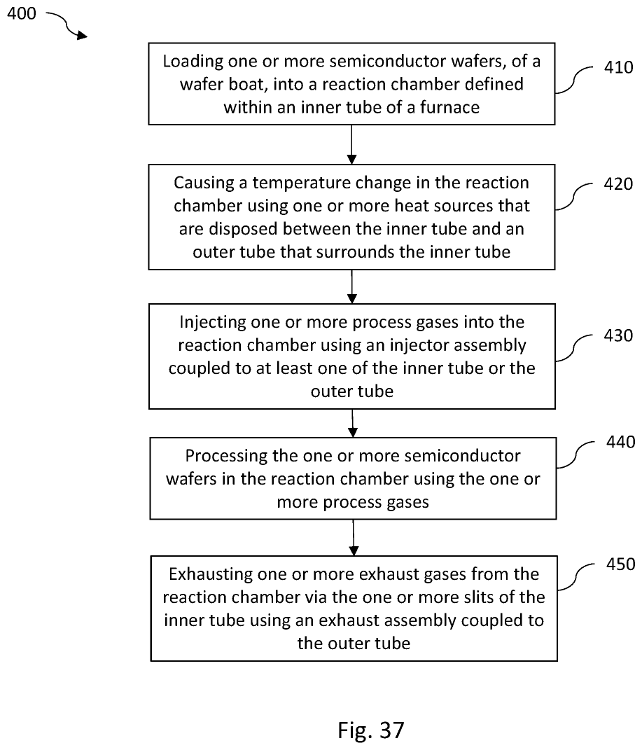

FIG. 37 is a flow chart that illustrates a method 400 of semiconductor processing according to embodiments of the present disclosure. The method 400 includes, at block 410, loading one or more semiconductor wafers 170, of a wafer boat 180, into a reaction chamber 112 defined within an inner tube (e.g., 110) of a furnace (e.g., 100). For example, loading the one or more semiconductor wafers 170 may include inserting the wafer boat 180 through the open end 118 of the inner tube 110. In some examples, inserting the wafer boat 180 through the open end 118 may include opening a door 131 of the furnace 100 and raising the wafer boat 180 in a vertical direction.

The method 400 includes, at block 420, causing a temperature change in the reaction chamber 112 using one or more heat sources 140 that are disposed between the inner tube 110 and an outer tube 130 that surrounds the inner tube 110.

The method 400 includes, at block 430, injecting one or more process gases 102 into the reaction chamber 112 using an injector assembly 150 coupled to at least one of the inner tube 110 or the outer tube 130.

The method 400 includes, at block 440, processing the one or more semiconductor wafers 170 in the reaction chamber 112 using the one or more process gases 102. For example, processing the one or more semiconductor wafers 170 may include forming a dummy gate layer over one or more fins or nanosheets. Forming the dummy gate layer may include performing at least one deposition-annealing-etching cycle, of a silicon-containing layer, configured to reduce seam void and bending of the dummy gate layer.

The method 400 includes, at block 450, exhausting one or more exhaust gases 104 from the reaction chamber 112 via the one or more slits 120 of the inner tube 110 using an exhaust assembly 160 coupled to the outer tube 130. For example, at least one of processing the one or more semiconductor wafers 170 or exhausting the one or more exhaust gases 104 may include operating a pump 166 that is coupled to the exhaust assembly 160 to create a vacuum pressure, in the reaction chamber 112, in a range between about 10 mTorr and about 50 Torr.

It will be understood that not all advantages have been necessarily discussed herein, no particular advantage is required for all embodiments or examples, and other embodiments or examples may offer different advantages.

Some embodiments of the present provide a furnace for semiconductor processing that includes: an inner tube defining a reaction chamber and including: a sidewall defined along a longitudinal axis of the inner tube and including one or more slits defined through the sidewall in a radial direction with respect to the longitudinal axis, wherein the one or more slits include at least one of: a first slit with a width in a range between 10 mm and 100 mm; or a plurality of separate slits with a total number in a range between 2 and 15; a closed end substantially enclosing the reaction chamber; and an open end opposite the closed end with respect to the longitudinal axis, wherein the reaction chamber is configured to be loaded with one or more semiconductor wafers via the open end; an outer tube that surrounds the inner tube; one or more heat sources configured to cause a temperature change in the reaction chamber; an injector assembly coupled to at least one of the inner tube or the outer tube and configured to inject one or more process gases into the reaction chamber; and an exhaust assembly coupled to the outer tube and configured to exhaust one or more exhaust gases from the reaction chamber via the one or more slits of the inner tube.

Some embodiments of the present disclosure provide a method of semiconductor processing that includes: loading one or more semiconductor wafers, of a wafer boat, into a reaction chamber defined within an inner tube of a furnace, the inner tube including: a sidewall defined along a longitudinal axis of the inner tube, wherein one or more slits are defined through the sidewall in a radial direction with respect to the longitudinal axis, and wherein the one or more slits include at least one of: a first slit with a width in a range between 10 mm and 100 mm; or a plurality of separate slits with a total number in a range between 2 and 15; a closed end substantially enclosing the reaction chamber; and an open end opposite the closed end with respect to the longitudinal axis, wherein loading the one or more semiconductor wafers includes inserting the wafer boat through the open end; causing a temperature change in the reaction chamber using one or more heat sources that are disposed between the inner tube and an outer tube that surrounds the inner tube; injecting one or more process gases into the reaction chamber using an injector assembly coupled to at least one of the inner tube or the outer tube; processing the one or more semiconductor wafers in the reaction chamber using the one or more process gases; and exhausting one or more exhaust gases from the reaction chamber via the one or more slits of the inner tube using an exhaust assembly coupled to the outer tube.

Some embodiments of the present disclosure provide an inner tube of a furnace for semiconductor processing that includes: a sidewall defined along a longitudinal axis of the inner tube and including one or more slits defined through the sidewall in a radial direction with respect to the longitudinal axis, wherein the one or more slits include: a sidewall portion defined in the sidewall; and a top portion connected to the sidewall portion and defined in a closed end of the inner tube, wherein the closed end substantially encloses a reaction chamber defined within the inner tube; and an open end opposite the closed end with respect to the longitudinal axis, wherein the reaction chamber is configured to be loaded with one or more semiconductor wafers via the open end.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A furnace for semiconductor processing, comprising:
an inner tube defining a reaction chamber and including:
a sidewall defined along a longitudinal axis of the inner tube and including one or more slits defined through the sidewall in a radial direction with respect to the longitudinal axis,
wherein the one or more slits include at least one of:
a first slit with a width in a range between 10 mm and 100 mm; or
a plurality of separate slits with a total number in a range between 2 and 15;
a closed end substantially enclosing the reaction chamber; and
an open end opposite the closed end with respect to the longitudinal axis, wherein the reaction chamber is configured to be loaded with one or more semiconductor wafers via the open end;
an outer tube that surrounds the inner tube;
one or more heat sources configured to cause a temperature change in the reaction chamber;
an injector assembly coupled to at least one of the inner tube or the outer tube and configured to inject one or more process gases into the reaction chamber; and
an exhaust assembly coupled to the outer tube and configured to exhaust one or more exhaust gases from the reaction chamber via the one or more slits of the inner tube.

2. The furnace of claim 1, wherein the one or more slits consist of the first slit with the width in the range between 10 mm and 100 mm.

3. The furnace of claim 2, wherein the first slit is parallel to the longitudinal axis and the width of the first slit is fixed.

4. The furnace of claim 2, wherein the first slit is perpendicular to the longitudinal axis and the width of the first slit is fixed.

5. The furnace of claim 2, wherein the first slit is a cross slit that includes a first portion parallel to the longitudinal axis and a second portion perpendicular to the first portion.

6. The furnace of claim 1, wherein the one or more slits include the plurality of separate slits.

7. The furnace of claim 6, wherein the plurality of separate slits are parallel to the longitudinal axis.

8. The furnace of claim 6, wherein the plurality of separate slits are perpendicular to the longitudinal axis.

9. The furnace of claim 6, wherein the plurality of separate slits are cross slits that include a first portion parallel to the longitudinal axis and a second portion perpendicular to the first portion.

10. The furnace of claim 1, wherein the one or more slits include the first slit with the width in the range between 10 mm and 100 mm.

11. The furnace of claim 10, wherein the first slit is parallel to the longitudinal axis and defines:
a first end;
a second end opposite the first end with respect to the longitudinal axis;
a full height between the first end and the second end;
a first width at the first end that corresponds to the full height;
a second width at the second end; and
a third width between the first end and the second end,
wherein the width of the first slit varies such that at least two widths, of the first width, the second width, and the third width, are different from each other.

12. The furnace of claim 11, wherein, at least one of:
the third width is a maximum width of the first slit and edges of the first slit are curved;
the third width is the maximum width of the first slit and edges of the first slit are straight;
the third width is a minimum width of the first slit and edges of the first slit are curved; or
the third width is the minimum width of the first slit and edges of the first slit are straight.

13. The furnace of claim 11, wherein a first edge, of the first slit, is at a first angle that is non-parallel with respect to the longitudinal axis and a second edge, of the first slit, is at a second angle that is non-parallel with respect to the longitudinal axis, and wherein, at least one of:
the width of the first slit varies linearly from the first end to the second end and the first width is less than the second width;
the width of the first slit varies linearly from the first end to the second end and the first width is greater than the second width;
the width of the first slit varies linearly along a first portion of the first slit that includes the first end, the width of the first slit is fixed along a second portion of the first slit that includes the second end, and the first width is less than the second width;
the width of the first slit varies linearly along the first portion of the first slit that includes the first end, the width of the first slit is fixed along the second portion of the first slit that includes the second end, and the first width is greater than the second width;
the width of the first slit is fixed along the first portion of the first slit that includes the first end, the width of the first slit varies linearly along the second portion of the first slit that includes the second end, and the first width is less than the second width; or
the width of the first slit is fixed along the first portion of the first slit that includes the first end, the width of the first slit varies linearly along the second portion of the first slit that includes the second end, and the first width is greater than the second width.

14. The furnace of claim 11, wherein the width of the first slit is fixed at the first width along a first portion of the first slit that includes the first end,
wherein the width of the first slit is fixed at the second width along a second portion of the first slit that includes the second end,
wherein first and second shoulders are defined, at an intersection of the first and second portions, along edges of the first slit,
wherein one or more step changes in the width are defined at the first and second shoulders,
wherein the first and second shoulders define one or more angles with respect to the edges, and
wherein, at least one of:
the first width is less than the second width and the one or more angles are right angles;
the first width is less than the second width and the one or more angles are oblique angles;
the first width is greater than the second width and the one or more angles are right angles; or
the first width is greater than the second width and the one or more angles are oblique angles.

15. The furnace of claim 11, wherein the width of the first slit is fixed at the first width along a first portion of the first slit that includes the first end,
wherein the width of the first slit is fixed at the second width along a second portion of the first slit that includes the second end,
wherein the width of the first slit is fixed at the third width along a third portion of the first slit between the first end and the second end,
wherein a plurality of shoulders are defined, between the first and third portions and between the second and third portions, along edges of the first slit,
wherein one or more step changes in the width are defined at the plurality of shoulders,
wherein the plurality of shoulders define one or more angles with respect to the edges, and
wherein, at least one of:
the first width is less than the second width, the second width is less than the third width, and the one or more angles are right angles;
the first width is less than the second width, the second width is less than the third width, and the one or more angles are oblique angles;
the first width is greater than the second width, the first width is less than the third width, and the one or more angles are right angles;
the first width is greater than the second width, the first width is less than the third width, and the one or more angles are oblique angles;
the first width is equal to the second width, the first width is greater than the third width, and the one or more angles are right angles;
the first width is equal to the second width, the first width is greater than the third width, and the one or more angles are oblique angles;
the first width is equal to the second width, the first width is less than the third width, and the one or more angles are right angles;
the first width is equal to the second width, the first width is less than the third width, and the one or more angles are oblique angles;
the first width is less than the second width, the first width is greater than the third width, and the one or more angles are right angles;
the first width is less than the second width, the first width is greater than the third width, and the one or more angles are oblique angles;
the first width is greater than the second width, the second width is greater than the third width, and the one or more angles are right angles; or
the first width is greater than the second width, the second width is greater than the third width, and the one or more angles are oblique angles.

16. A method of semiconductor processing, comprising:
loading one or more semiconductor wafers, of a wafer boat, into a reaction chamber defined within an inner tube of a furnace, the inner tube including:
a sidewall defined along a longitudinal axis of the inner tube, wherein one or more slits are defined through the sidewall in a radial direction with respect to the longitudinal axis, and
wherein the one or more slits include at least one of:
a first slit with a width in a range between 10 mm and 100 mm; or
a plurality of separate slits with a total number in a range between 2 and 15;
a closed end substantially enclosing the reaction chamber; and
an open end opposite the closed end with respect to the longitudinal axis, wherein loading the one or more semiconductor wafers includes inserting the wafer boat through the open end;
causing a temperature change in the reaction chamber using one or more heat sources that are disposed between the inner tube and an outer tube that surrounds the inner tube;
injecting one or more process gases into the reaction chamber using an injector assembly coupled to at least one of the inner tube or the outer tube;
processing the one or more semiconductor wafers in the reaction chamber using the one or more process gases; and
exhausting one or more exhaust gases from the reaction chamber via the one or more slits of the inner tube using an exhaust assembly coupled to the outer tube.

17. The method of claim 16, wherein inserting the wafer boat through the open end includes:
opening a door of the furnace; and
raising the wafer boat in a vertical direction.

18. The method of claim 16, wherein processing the one or more semiconductor wafers includes:
forming a dummy gate layer over one or more fins or nanosheets, wherein forming the dummy gate layer includes performing at least one deposition-annealing-etching cycle, of a silicon-containing layer, configured to reduce seam void and bending of the dummy gate layer.

19. The method of claim 16, wherein at least one of processing the one or more semiconductor wafers or exhausting the one or more exhaust gases includes:
operating a pump that is coupled to the exhaust assembly to create a vacuum pressure, in the reaction chamber, in a range between about 10 mTorr and about 50 Torr.

20. An inner tube of a furnace for semiconductor processing, comprising:
a sidewall defined along a longitudinal axis of the inner tube and including one or more slits defined through the sidewall in a radial direction with respect to the longitudinal axis,
wherein the one or more slits include:
a sidewall portion defined in the sidewall; and
a top portion connected to the sidewall portion and defined in a closed end of the inner tube, wherein the closed end substantially encloses a reaction chamber defined within the inner tube; and
an open end opposite the closed end with respect to the longitudinal axis, wherein the reaction chamber is configured to be loaded with one or more semiconductor wafers via the open end.
